(19) United States
(12) Patent Application Publication
(10) Pub. No.: US 2015/0022889 A1
(43) Pub. Date: Jan. 22, 2015

(54) DISPLAY DEVICE

(71) Applicant: Sony Corporation, Tokyo (JP)

(72) Inventor: Toru Amano, Tokyo (JP)

(73) Assignee: Sony Corporation, Tokyo (JP)

(21) Appl. No.: 14/376,852

(22) PCT Filed: Dec. 13, 2012
(86) PCT No.: PCT/JP2012/082332

§ 371 Date: Aug. 6, 2014

(30) Foreign Application Priority Data
Feb. 13, 2012 (JP) 2012-028426

(51) Int. Cl. G02B 27/00; H05K 5/06

(52) U.S. Cl. CPC G02B 27/0006; H05K 5/065; G02B 5/30
USPC 359/513

(57) ABSTRACT

Provided is a display device including a housing having an internal space and in which a disposition hole in communication with the internal space is formed, a transparent protection plate mounted on the housing in a state of covering the disposition hole via a waterproofing structure preventing entrance of moisture into the internal space from the disposition hole, an electrostatic capacity panel having a transparent electrode, a polarizing plate that transforms penetrating light into polarized light, and a display panel that displays an image or a video. The polarizing plate, the electrostatic capacity panel, and the display panel are disposed in the housing, as well as the polarizing plate is disposed between the transparent protection plate and the electrostatic capacity panel.

### TECHNICAL FIELD

The present technology relates to the technical field about display devices. In particular, the present technology relates to the technical field of ensuring waterproofing performance without impairing functionality of the polarizing plate by providing a waterproofing structure between a housing and a transparent protection plate, and disposing an electrostatic capacity panel, a polarizing plate, and a display panel inside the housing.

### BACKGROUND ART

There are video cameras, still cameras, television receivers, personal computers, and the like that have a display panel such as a liquid crystal panel or an organic EL (Electro Luminescence) panel.

In display devices having such a display panel, the display panel is disposed inside a housing and the display panel is protected by being covered from the outer surface side by a transparent protection plate mounted on the housing (for example, refer to Patent Literature 1).

In the display device described in Patent Literature 1, a polarizing plate is disposed on the outer surface side of the transparent protection plate, and it is difficult to externally visually recognize a transparent electrode disposed inside the housing by the action of the polarizing plate.

### CITATION LIST

### Patent Literature

Patent Literature 1: JP 2011-99880A

### SUMMARY OF INVENTION

### Technical Problem

Incidentally, in recent years, improvement of functionality also in display devices has been attempted, for example, types having waterproofing performance in which the entrance of moisture to the internal space of the housing is prevented exist.

However, in the display device described in Patent Literature 1, although it is possible to ensure waterproofing in the internal space of the housing by providing a waterproofing structure between the housing and the transparent protection plate, since the polarizing plate is provided on the outer surface side of the transparent protection plate, when moisture adheres to the outer peripheral surface of the polarizing plate, functionality of the polarizing plate is impaired by the entrance of moisture into the interior of the polarizing plate.

Thus, the display device of the present technology overcomes the problem described above, and has the object of ensuring waterproofing performance without impairing functionality of the polarizing plate.

### Solution to Problem

First, in order to solve the above-described problem, a display device includes a housing having an internal space and in which a disposition hole in communication with the internal space is formed, a transparent protection plate mounted on the housing in a state of covering the disposition hole via a waterproofing structure preventing entrance of moisture into the internal space from the disposition hole, an electrostatic capacity panel having a transparent electrode, a polarizing plate that transforms penetrating light into polarized light, and a display panel that displays an image or a video. The polarizing plate, the electrostatic capacity panel, and the display panel are disposed in the housing, as well as the polarizing plate is disposed between the transparent protection plate and the electrostatic capacity panel.

Accordingly, in the display device, the polarizing plate is covered from the outside by the transparent protection plate mounted on the housing via the waterproofing structure.

Second, in the display device, it is desired that the transparent protection plate be formed from glass.

By forming the transparent protection plate from glass, the strength of the transparent protection plate increases.

Third, in the display device, it is desired that the transparent protection plate be formed from a resin material.

By forming the transparent protection plate from a resin material, the transparent protection plate becomes lightweight.

Fourth, in the display device, it is desired that a double-sided tape having both surfaces stuck to the housing and the transparent protection plate be used as the waterproofing structure.

By using, as the waterproofing structure, the double-sided tape having both surfaces stuck to the housing and the transparent protection plate, the entrance of water into the internal space from the disposition hole is prevented by the double-sided tape.

Fifth, in the display device, it is desired that an outer shape of the transparent protection plate be larger than an outer shape of the polarizing plate, the waterproofing structure be provided between the housing and an outer peripheral section of the transparent protection plate, and at least a part of the polarizing plate be disposed on the disposition hole.

By making the outer shape of the transparent protection plate larger than the outer shape of the polarizing plate, providing the waterproofing structure between the housing and the outer peripheral section of the transparent protection plate, and disposing at least a part of the polarizing plate in the disposition hole, the outer periphery section of the transparent protection plate is positioned on the periphery side of the polarizing plate.

Sixth, in the display device, it is desired that a step surface be formed on an outer peripheral side of the disposition hole in the housing, an inside surface continuing to the step surface be formed as a mounting surface positioned on the internal space side more than an outside surface that continues to the disposition hole and continues to the step surface, and the outer peripheral section of the transparent protection plate be mounted on the mounting surface.

By forming the inside surface continuing to the step surface as a mounting surface positioned on the internal space side more than the outside surface continuing to the disposition hole and continuing to the step surface, and the outer peripheral section of the transparent protection plate being mounted on the mounting surface, the amount of the transparent protection plate protruding from the housing to the outside is reduced.

### Advantageous Effects of Invention

The display device of the present technology includes: a housing having an internal space and in which a disposition hole in communication with the internal space is formed; a transparent protection plate mounted on the housing in a state of covering the disposition hole via a waterproofing structure preventing the entrance of moisture into the internal space from the disposition hole; an electrostatic capacity panel having a transparent electrode; a polarizing plate that transforms penetrating light into polarized light; and a display panel that displays an image or a video, wherein the polarizing plate, the electrostatic capacity panel, and the display panel are disposed inside the housing, as well as the polarizing plate is disposed between the transparent protection plate and the electrostatic capacity panel.

Accordingly, since the polarizing plate is disposed on the inside of the transparent protection plate mounted on the housing via the waterproofing structure, there is no adherence of moisture to the outer peripheral surface of the polarizing plate, and thus it is possible to ensure waterproofing performance without impairing functionality of the polarizing plate.

### BRIEF DESCRIPTION OF DRAWINGS

FIG. 1, together with FIG. 2 to FIG. 4, shows a display device of the present technology, and the present figure is a perspective view of the display device.

FIG. 2 is a perspective view showing the state when the display device is viewed from a different direction to that of FIG. 1.

FIG. 3 is an enlarged sectional view showing a part of the display device.

FIG. 4 is a block diagram of the display device.

### DESCRIPTION OF EMBODIMENTS

Hereinafter, the best mode for carrying out the display device of the present technology will be explained following the accompanying drawings.

In the best mode shown below, the display device of the present technology is applied to a digital still camera.

However, the application scope of the present technology is not limited to digital still cameras, and, for example, can be widely applied to imaging devices such as video cameras; portable terminal devices such as mobile telephones and PDA (Personal Digital Assistant); information processing devices such as personal computers; and various display devices having a display panel such as television receivers and display monitors.

In the explanation below, the front-back, up-down, and left-right directions are shown in the direction seen from the photographer at the time of imaging with the display device (digital still camera). Accordingly, the imaged subject side is the front side, and the photographer side is the back side.

Also, the front-back, up-down, and right-left directions shown below are for convenience of explanation, and implementation of the present technology is not limited to these directions.

### [Configuration of Display Device]

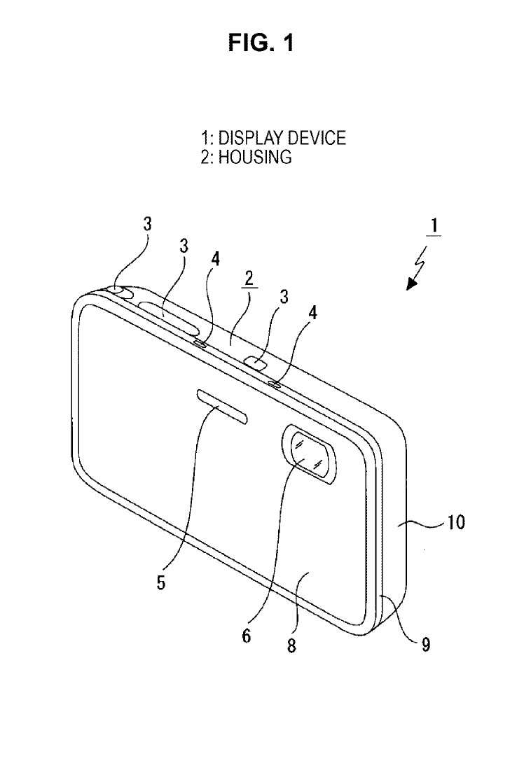

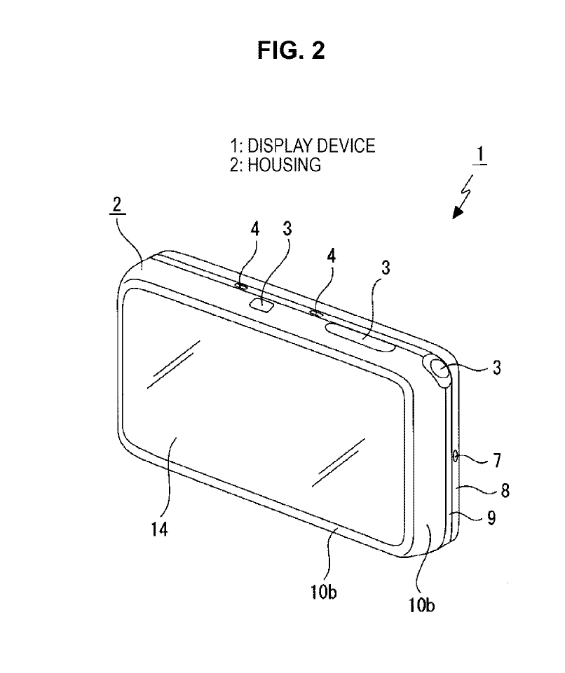

A display device (digital still camera) 1 is formed from a box-shaped housing 2 open in the back direction and each necessary section disposed inside or outside the housing 2 (refer to FIG. 1 and FIG. 2).

Various operation sections 3, 3, . . . are disposed on the top surface of the housing 2. As the operation sections 3, 3, . . . , for example, a power button for supplying power, a shutter button that is operated when imaging, a zoom knob for performing zooming, and the like are disposed.

Microphones 4, 4′ are disposed on a top surface section of the housing 2.

In a top end section on the front side of the housing 2, a flash 5 for irradiating auxiliary light when imaging and an imaging lens 6 for capturing an image of the imaged subject are disposed side by side. Inside the housing 2, a lens optical system in which various lens or a lens group including the photographing lens 6 are disposed along the optical axis is disposed.

A speaker 7 is disposed on a side surface section of the housing 2.

The housing 2 has a front panel 8, a frame 9, and a cabinet 10, and the front panel 8, the frame 9, and the cabinet 10 are joined in order in the front-back direction.

The front panel 8 is formed in a horizontally-long roughly rectangular plate shape facing the front-back direction.

The frame 9 is formed in a horizontally-long roughly rectangular frame shape.

The cabinet 10 is formed in a horizontally-long roughly rectangular frame shape, and the front-to-back width is larger than the front-to-back width of the frame 9. An opening on the back side of the cabinet 10 is formed as a disposition hole 10a.

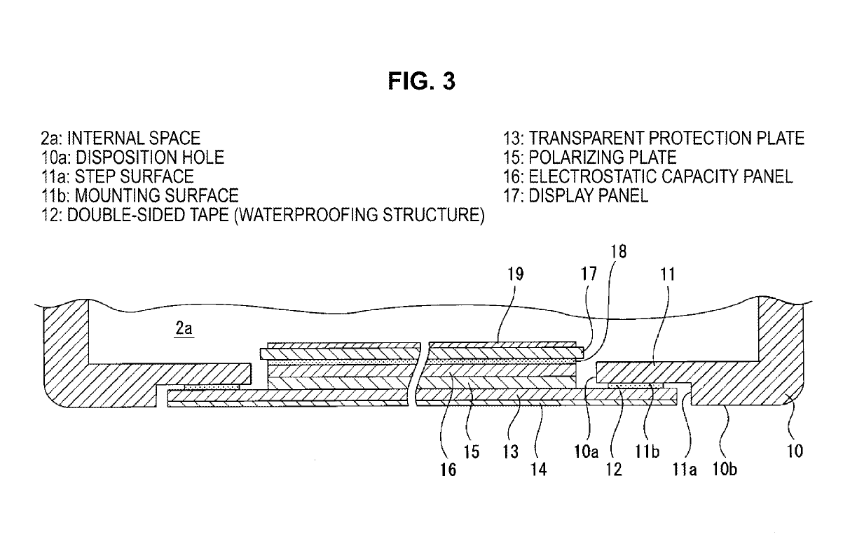

A back end section of the cabinet 10 is provided as a mounting section 11 formed in an annular shape (refer to FIG. 3). The mounting section 11 has a step surface 11a that faces inward and that is formed in an annular shape, and a mounting surface 11b that continues to the front edge of the step surface 11a and that faces backwards. The mounting surface 11b is a surface that continues to the front edge of the step surface 11a and faces backwards, in other words, is positioned on the front side more than a back surface 10b of the cabinet 10.

The outer peripheral section of a transparent protection plate 13 is mounted on the mounting surface 11b of the cabinet 10 by a double-sided tape 12. The double-sided tape 12 is provided as a waterproofing structure preventing the entrance of water into the internal space 2a of the housing 2, and is formed in a frame shape.

By using, as described above, the double-sided tape 12 in which both surfaces are stuck to the mounting section 11 and the transparent protection plate 13 of the housing 2 as a waterproofing structure, it is possible to simply and assuredly ensure waterproofing performance.

Also, the waterproofing structure is not limited to the double-sided tape 12. The waterproofing structure, for example, may be a structure where an acrylic, silicon, epoxy, urethane, or fluorine-based resin or the like lies between the mounting section 11 and the transparent protection plate 13. Also, as the waterproofing structure, an O-ring formed from a material having elasticity such as rubber may be used.

The transparent protection plate 13 is, for example, formed from glass (reinforced glass). Also, the transparent protection plate 13 is not limited to glass, and the transparent protection plate 13 may be formed from an acrylic-based, polycarbonate-based, polyethylene terephthalate-based, cycloolefin-based, or the like resin material.

By forming the transparent protection plate 13 from glass, it is possible to reduce scratching, and also, since birefringence is small, it is possible to improve visibility of an image or a video displayed by the after-described display panel. On the other hand, by forming the transparent protection plate 13 from a resin material, it is possible to reduce the weight of the display device 1.

A protection sheet 14 is stuck on the back surface of the transparent protection plate 13. As the protection sheet 14, for example, a low-reflectance sheet, a sheet made to have a hard coating in order to prevent scratching of the transparent protection plate 13, or the like can be used.

Inside the housing 2, a polarizing plate 15, an electrostatic capacity panel 16, and a display panel 17 are disposed in a laminar state in order from the back side to the front surface side of the transparent protection plate 13. The polarizing plate 15, the electrostatic capacity panel 16, and the display panel 17 have an outer shape slightly smaller than the outer shape of the transparent protection plate 13, and are disposed in a laminar state on the front side of the part of the transparent protection plate 13 excluding the outer peripheral section.

The polarizing plate 15 has a function of converting penetrating light into linearly polarized light, and has a base material (film) and ¼ lambda phase difference plates disposed in a laminar state on both the front and back surface sides of the base material.

The polarizing plate 15, as described above, is disposed in a laminar state on the front side of the part of the transparent protection plate 13 excluding the outer peripheral section. Accordingly, by the outer peripheral section of the transparent protection plate 13 being mounted on the mounting section 11, at least a part of the polarizing plate 15 is disposed in the disposition hole 10a.

The electrostatic capacity panel 16 has a function as a touch panel by an electrostatic capacity method, and carries out position detection by catching the change in electrostatic capacity between a fingertip and a conductive membrane. The electrostatic capacity panel 16 has an insulation film and, for example, a diamond-shaped electrode pattern formed by a transparent electrode such as ITO (Indium Tin Oxide).

It is operated by, when a finger approaches the electrostatic capacity panel 16, capturing the change in electrostatic capacity of the transparent electrode near such so as to perform position detection, and various operations operated according to the detected position are executed.

Since the electrostatic capacity panel 16 performs operations by a finger approaching from behind the transparent protection plate 13, at the time of operation, there are cases where the transparent protection plate 13 is pressed from behind by a finger, and, as mentioned above, by forming the transparent protection plate 13 from glass, deformation or damaging of the transparent protection plate 13 when operated by pressing can thus be reduced.

As the display panel 17, for example, a spontaneous-type organic EL (Electro Luminescence) panel can be used.

By using an organic EL panel as the display panel 17, there is no need to separately provide a light source functioning as a backlight or sidelight, or a light-guiding plate or the like for guiding light emitted from a light source provided as a sidelight, and thus making the display device 1 thinner and smaller is possible.

Also, the display panel 17 is not limited to an organic EL panel, and another display panel, such as a liquid crystal panel, may be used.

The display panel 17 is stuck to the electrostatic capacity panel 16 by an adhesive layer 18. As the adhesive layer 18, for example, an acrylic-based transparent material can be used.

A light-blocking sheet 19 is stuck to the front surface of the display panel 18.

### [Action of Display Device]

In the display device 1 configured as described above, an image or a video displayed on the display panel 17 can be visually recognized externally via the transparent protection plate 13, as well as operations to the electrostatic capacity panel 16 for an operation section (operation icons or the like) displayed on the display panel 17 are possible.

At this time, by an action of the polarizing plate 15, it is in a state in which it is difficult to visually recognize the pattern of the transparent electrode of the electrostatic capacity panel 16 disposed between the polarizing plate 15 and the display panel 17.

### [Circuit Configuration of Display Device]

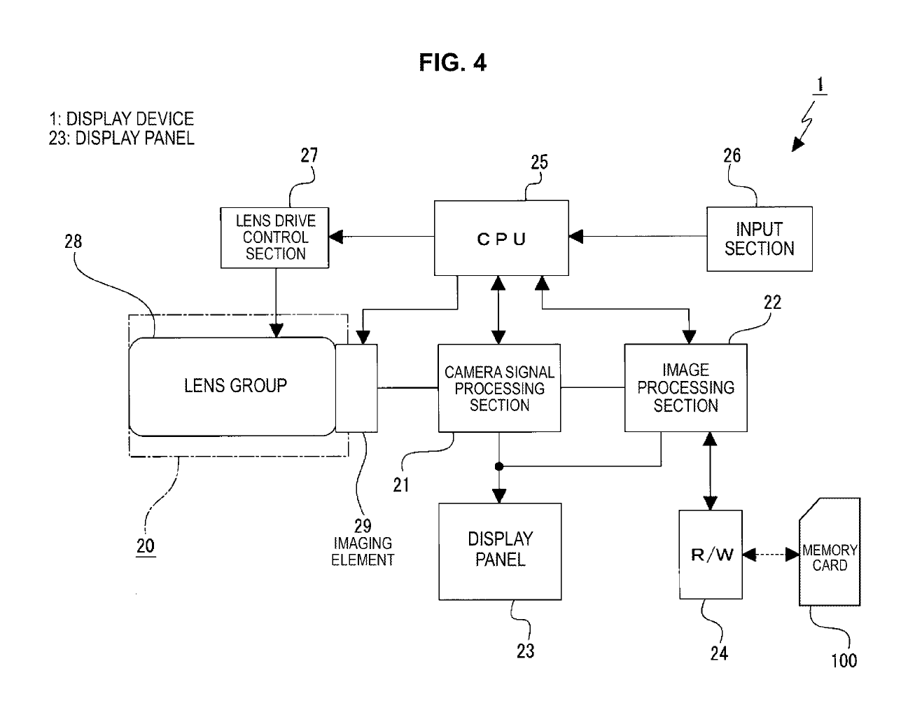

An example of the circuit configuration of the display device (digital still camera) 1 is shown below (refer to FIG. 4).

The display device 1 includes: a camera block 20 having an imaging function; a camera signal processing section 21 that performs signal processing, such as analog-digital conversion of the signal of the image which is imaged; and an image processing section 22 that performs recording and reproduction of the image signal. Also, the display device 1 includes: a display panel 23 (display panel 17) that displays the imaged image or the like; an R/W (Reader/Writer) 24 that performs writing and reading of the image signal to/from a memory card 100; a CPU (Central Processing Unit) 25 that controls the entire display device 1, an input section 26 (operation sections 3, 3, . . . ) formed from various switches for carrying out necessary operations by a user, and a lens driving control section 27 that controls driving of the lenses disposed in the camera block 20.

The camera block 20 is configured by a lens optical system including the lens group 28, or an imaging element 29, such as a CCD (Charge Coupled Device) or a CMOS (Complementary Metal-Oxide Semiconductor), or the like.

The camera signal processing section 21 performs various signal processes on the output signal from the imaging element 29, such as conversion to a digital signal, noise removal, image quality correction, and conversion to luminance and color difference signals.

The image processing section 22 performs compression encoding and expansion decoding or conversion processing of a data specification, such as resolution, or the like based on a given image data format.

The display panel 23 has a function of displaying the operation state of the input section 26 by the user or various data, such as the imaged image.

The R/W 24 performs writing image data encoded by the image processing section 22 to the memory card 100 and reading image data recorded on the memory card 100.

The CPU 25 functions as a control processing section controlling each circuit block provided in the display device 1, and controls each circuit block based on an instruction input signal from the input section 26.

The input section 26 outputs to the CPU 25 an instruction input signal according to an operation by the user.

The lens driving control section 27 is a not-shown motor or like that drives each lens of the lens group 28 based on a control signal from the CPU 25.

The memory card 100, for example, is a semiconductor memory detachable from a slot connected to the R/W 24.

The operation of the display device 1 is explained below.

In an imaging standby state, under control by the CPU 25, a signal of the image imaged in the camera block 20 is output to the display panel 23 via a camera signal processing section 21, and displayed as a camera-through image. Also, when an instruction input signal for zooming is input from the input section 26, the CPU 25 outputs a control signal to the lens driving control section 27 and a given lens of the lens group 28 is moved based on the control of the lens driving control section 27.

When a not-shown shutter of the camera block 20 is operated by an instruction input signal from the input section 26, the signal of the image which is image is output to the image processing section 22 from the camera signal processing section 21, and then compression encoding processed and converted into digital data having a given data format. The converted data is output to the R/W 24 and written on the memory card 100.

Focusing is performed by, for example, when the shutter button of the input section is half depressed or when fully depressed for recording (imaging), or the like, the lens driving control section 27 moving a given lens of the lens group 28 based on a control signal from the CPU 25.

Zooming is performed by, for example, when the zoom knob of the input section 26 is operated, the lens driving control section 27 moving a given lens of the lens group 28 based on a control signal from the CPU 25.

When reproducing image data recorded on the memory card 100, in accordance with an operation of the input section 26, given image data is read from the memory card 100 by the R/W 24, and after expansion decoding processing is performed by the image processing section 22, a reproduction image signal is output to the image panel 23 and a reproduced image is displayed.

### SUMMARY

As described above, in the display device 1, the polarizing plate 15, the electrostatic capacity panel 16, and the display panel 17 are disposed inside the housing 2, as well as the polarizing plate 15 is disposed between the transparent protection plate 13 mounted on the housing 2 by the double-sided tape 12 provided as a waterproofing structure and the electrostatic capacity panel 16.

Accordingly, since the polarizing plate 15 is disposed on the inside of the transparent protection plate 13 mounted on the housing 2 by the double-sided tape 12 provided as a waterproofing structure, there is no adherence of moisture to the outer peripheral surface of the polarizing plate, and thus it is possible to ensure waterproofing performance without the impairment of the functionality of the polarizing plate.

Also, since the adherence of moisture to the outer peripheral surface of the polarizing plate 15 is prevented by disposing the polarizing plate 15 inside the housing 2 and placing a waterproofing structure between the housing and the transparent protection plate 13, functionality and waterproofing performance of the polarizing plate can be ensured without an increase in costs and without increasing the thickness of the display device 1.

Furthermore, since the outer shape of the transparent protection plate 13 is larger than the outer shape of the polarizing plate 15 and at least a part of the polarizing plate 15 is disposed on the disposition hole 10a, a waterproofing structure such as the double-sided tape 12 can be easily provided between the housing 2 and the outer peripheral section of the transparent protection plate 13.

In addition, a step surface 11a is formed on the outer peripheral side of the disposition hole 10a of the housing 2 and the outer peripheral section of the transparent protection plate 13 is mounted on the mounting plate 11b positioned on the front side more than the back surface 10b of the cabinet 10.

Accordingly, the front surface of the transparent protection plate 13 is positioned in the front more than the back surface 10b of the cabinet 10, and the display device 1 can be made thinner that portion.

### [Present Technology]

The present technology may also be configured as below.

(1)

A display device including:

a housing having an internal space and in which a disposition hole in communication with the internal space is formed;

a transparent protection plate mounted on the housing in a state of covering the disposition hole via a waterproofing structure preventing entrance of moisture into the internal space from the disposition hole;

an electrostatic capacity panel having a transparent electrode;

a polarizing plate that transforms penetrating light into polarized light; and

a display panel that displays an image or a video,

wherein the polarizing plate, the electrostatic capacity panel, and the display panel are disposed in the internal space, as well as the polarizing plate is disposed between the transparent protection plate and the electrostatic capacity panel.

(2)

The display device according to (1), wherein the transparent protection plate is formed from glass.

(3)

The display device according to (1), wherein the transparent protection plate is formed from a resin material.

(4)

The display device according to any of (1) to (3), wherein a double-sided tape having both surfaces stuck to the housing and the transparent protection plate is used as the waterproofing structure.

(5)

The display device according to any of (1) to (4), wherein

an outer shape of the transparent protection plate is larger than an outer shape of the polarizing plate,

the waterproofing structure is provided between the housing and an outer peripheral section of the transparent protection plate, and

at least a part of the polarizing plate is disposed on the disposition hole.

(6)

The display device according to (5), wherein

a step surface is formed on an outer peripheral side of the disposition hole in the housing,

an inside surface continuing to the step surface is formed as a mounting surface positioned on the internal space side more than an outside surface that continues to the disposition hole and continues to the step surface, and

the outer peripheral section of the transparent protection plate is mounted on the mounting surface.

The specific shapes and structures of each part shown in the best mode of the invention described above merely show one example of concretization when implementing the present technology, and the technical scope of the present technology should not be interpreted as limited thereto.

### REFERENCE SIGNS LIST

1 display device
2 housing
2a internal space
10a disposition hole
11a step surface
11b mounting surface
12 double-sided tape (waterproofing structure)
13 transparent protection plate
15 polarizing plate
16 electrostatic capacity panel
17 display panel
23 display panel

1. A display device comprising:
a housing having an internal space and in which a disposition hole in communication with the internal space is formed;
a transparent protection plate mounted on the housing in a state of covering the disposition hole via a waterproofing structure preventing entrance of moisture into the internal space from the disposition hole;
an electrostatic capacity panel having a transparent electrode;
a polarizing plate that transforms penetrating light into polarized light; and
a display panel that displays an image or a video,
wherein the polarizing plate, the electrostatic capacity panel, and the display panel are disposed in the housing, as well as the polarizing plate is disposed between the transparent protection plate and the electrostatic capacity panel.

2. The display device according to claim 1, wherein the transparent protection plate is formed from glass.

3. The display device according to claim 1, wherein the transparent protection plate is formed from a resin material.

4. The display device according to claim 1, wherein a double-sided tape having both surfaces stuck to the housing and the transparent protection plate is used as the waterproofing structure.

5. The display device according to claim 1, wherein
an outer shape of the transparent protection plate is larger than an outer shape of the polarizing plate,
the waterproofing structure is provided between the housing and an outer peripheral section of the transparent protection plate, and
at least a part of the polarizing plate is disposed on the disposition hole.

6. The display device according to claim 5, wherein
a step surface is formed on an outer peripheral side of the disposition hole in the housing,
an inside surface continuing to the step surface is formed as a mounting surface positioned on the internal space side more than an outside surface that continues to the disposition hole and continues to the step surface, and
the outer peripheral section of the transparent protection plate is mounted on the mounting surface.
